(19) United States
(12) Patent Application Publication
(10) Pub. No.: US 2011/0155220 A1
(43) Pub. Date: Jun. 30, 2011

(54) SOLAR PANEL TILE STRUCTURE AND COMBINATION THEREOF

(76) Inventors: Shih-Wei Lee, Kaohsiung County (TW); Tien-Hsing Liang, Taipei City (TW); Chi-Hung Hou, Taipei City (TW); Chen-Hai Chiu, Hsinchu County (TW); Chiu-An Tseng, Kaohsiung County (TW)

(21) Appl. No.: 12/979,284

(22) Filed: Dec. 27, 2010

(30) Foreign Application Priority Data
Dec. 30, 2009 (TW) 098145975

(51) Int. Cl. H01L 31/042

(52) U.S. Cl. 136/251

(57) ABSTRACT

A solar panel tile structure capable of draining water includes a solar panel and a supporting plate for supporting the solar panel. At least one draining slot is formed on the supporting plate and disposed around the solar plate for draining the water surrounding the solar panel.

### BACKGROUND OF THE INVENTION

1. Field of the Invention

The present invention relates to a solar panel tile structure, and more particularly, to a solar panel tile structure with water-draining function.

2. Description of the Prior Art

Generally, a conventional solar panel can be disposed on an outside surface of a building. For example, the conventional solar panel can be installed on a housetop or an external wall so as to transform solar energy into electrical energy effectively. The conventional solar panel disposed on the housetop of the building can transform the solar energy into the electrical energy in a sunny day and can protect the building in a rainy day. However, the conventional solar panel tile can not drain water away from the solar panel effectively in the rainy day, so that electronic elements inside the solar panels of the conventional solar panel tile are damaged by the water easily. Thus, design of a solar panel tile structure capable of draining the water around the solar panel effectively is an important issue in the solar panel industry.

### SUMMARY OF THE INVENTION

The present invention provides a solar panel tile structure with water-draining function for solving above drawbacks.

According to the claimed invention, a solar panel tile structure includes a solar panel and a supporting plate for supporting the solar panel. At least one draining slot is formed on the supporting plate and disposed around the solar panel for draining water surrounding the solar panel.

According to the claimed invention, a solar panel tile structure combination includes a first solar panel tile structure and a second solar panel tile structure connected to the first solar panel tile structure. The first solar panel tile structure includes a first solar panel and a first supporting plate for supporting the first solar panel. At least one first draining slot is formed on the first supporting plate and disposed around the first solar panel for draining water surrounding the first solar panel. The second solar panel tile structure includes a second solar panel and a second supporting plate for supporting the second solar panel. At least one second draining slot is formed on the second supporting plate and disposed around the second solar panel for draining water surrounding the second solar panel and for draining the water from the first draining slot.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a first solar tile structure according to a preferred embodiment of the present invention.

FIG. 2 is a diagram of a solar tile structure combination according to the preferred embodiment of the present invention.

### DETAILED DESCRIPTION

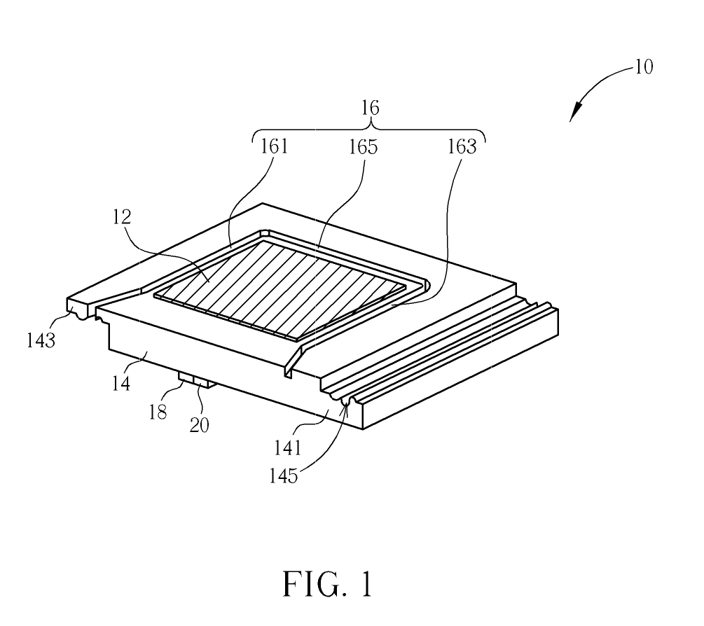

Please refer to FIG. 1. FIG. 1 is a diagram of a first solar tile structure 10 according to a preferred embodiment of the present invention. The first solar tile structure 10 includes a first solar panel 12 and a first supporting plate 14. The first solar tile structure 12 is disposed on the first supporting plate 14 by locking, gluing, or wedging. A first draining slot 16 is formed on the first supporting plate 14 and disposed around the first solar panel 12 for draining water surrounding the first solar panel 12. A first wedging portion 141 and a second wedging portion 143 are respectively formed on two lateral sides of the first supporting plate 14. A draining channel 145 is formed on the first wedging portion 141. The first wedging portion 141 and the second wedging portion 143 are structural portions capable of wedging with each other tightly. The first draining slot 16 includes a first ditch 161 disposed on a left side of the first supporting plate 14, a second ditch 163 disposed on a right side of the first supporting plate 14, and a third ditch 165 disposed on an upper side of the first supporting plate 14 and connected to the first ditch 161 and the second ditch 163. As shown in FIG. 1, the first ditch 161, the second ditch 163, and the third ditch 165 are connected and disposed around the first solar panel 12. In this embodiment, the first ditch 161 can be parallel to the second ditch 163 substantially, and the third ditch 165 can be perpendicular to the first ditch 161 and the second ditch 163 substantially. Because a height of the first solar panel 12 can substantially be higher than a height of the first supporting plate 14, the water on the first solar panel 12 can flow into the first draining slot 16 spontaneously, so as to drain the water out of the first solar tile structure 10 effectively.

For preventing the water from overflowing the first draining slot 16 onto the first solar panel 12 when the water flows from the third ditch 165 into the first ditch 161 and the second ditch 163, ends of the first ditch 161 and the second ditch 163 far from the third ditch 165 can bend outward the first supporting plate 14, so that the water flowing from the third ditch 165 into the first ditch 161 and the second ditch 163 can be guided toward two sides of the first solar tile structure 10 outwardly. The shape of the first draining slot 16 is not limited to the above-mentioned embodiment and depends on design demand. Besides, the first solar tile structure 10 can further include a transmission cable (not shown in figures) and a junction box 18 disposed on a side of the first supporting plate 14. Two ends of the transmission cable can be electrically connected to the first solar panel 12 and the junction box 18 respectively, for transmitting electricity transformed by the first solar panel 12 to the junction box 18. The first solar tile structure 10 can further include a battery module 20 electrically connected to the junction box 18 for storing the electricity received by the junction box 18.

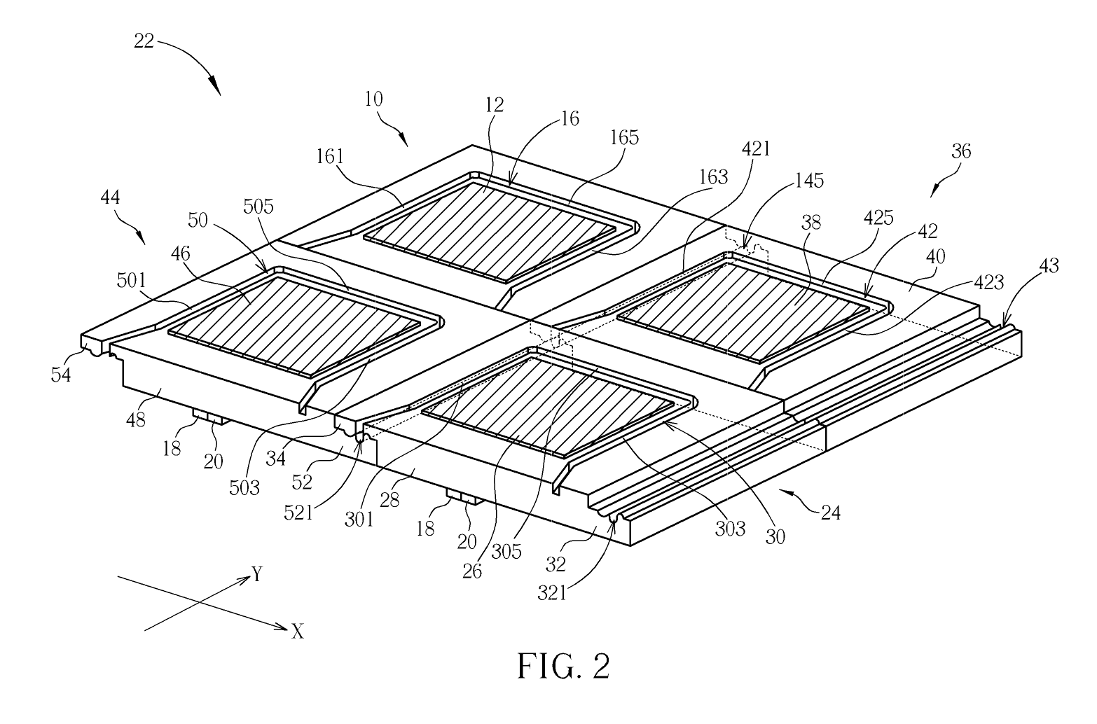

Please refer to FIG. 2. FIG. 2 is a diagram of a solar tile structure combination 22 according to the preferred embodiment of the present invention. A plurality of solar tile structures having the same structural design can be combined for forming the solar tile structure combination 22 as an array. For example, the solar tile structure combination 22 includes the first solar tile structure 10 and a second solar tile structure 24. The second solar tile structure 24 includes a second panel 26 and a second supporting plate 28 for supporting the second solar panel 26. At least one second draining slot 30 is formed on the second supporting plate 28 and disposed around the second solar panel 26 for draining water surrounding the second solar panel 26. A first wedging portion 32 and a second wedging portion 34 are formed on two lateral sides of the second supporting plate 28. A draining channel 321 is formed on the first wedging portion 32. The first wedging portion and the second wedging portion 34 are structural portions capable of wedging with each other tightly. Besides, the second draining slot 30 includes a fourth ditch 301 disposed on a left side of the second supporting plate 28, a fifth ditch 303 disposed on a right side of the second supporting plate 28, and a sixth ditch 305 disposed on an upper side of the second supporting plate 28 and connected to the fourth ditch 301 and the fifth ditch 303. The fourth ditch 301 can be parallel to the fifth ditch 303 substantially, and the sixth ditch 305 can be perpendicular to the fourth ditch 301 and the fifth ditch 303 substantially. Ends of the fourth ditch 301 and the fifth ditch 303 far from the sixth ditch 305 can bend outward the second supporting plate 28, so that the water flowing from the sixth ditch 305 into the fourth ditch 301 and the fifth ditch 303 can be guided toward two sides of the second solar tile structure 24 outwardly, so as to prevent the water from overflowing the second draining slot 30 onto the second solar panel 26.

The solar tile structure combination 22 can further include a third solar tile structure 36. As shown in FIG. 2, the third solar tile structure 38 includes a third panel 38 and a third supporting plate 40 for supporting the third solar panel 38. At least one third draining slot 42 is formed on the third supporting plate 40 and disposed around the third solar panel 38 for draining water surrounding the third solar panel 38. The third draining slot 42 includes a seventh ditch 421 disposed on a left side of the third supporting plate 40, an eighth ditch 423 disposed on a right side of the third supporting plate 40, and a ninth ditch 425 disposed on an upper side of the third supporting plate 40 and connected to the seventh ditch 421 and the eighth ditch 423. Ends of the seventh ditch 421 and the eighth ditch 423 far from the ninth ditch 425 can bend outward the third supporting plate 40, so that the water flowing from the ninth ditch 425 into the seventh ditch 421 and the eighth ditch 423 can be guided toward two sides of the third solar tile structure 36 outwardly, so as to prevent the water from overflowing the third draining slot 42 onto the third solar panel 38. Besides, a first wedging portion and a second wedging portion can be formed on two lateral sides of the third supporting plate 40, so that the third solar tile structure 36 can be connected to the adjacent solar tile structure by the first wedging portion and the second wedging portion. A draining channel 43 is formed on the first wedging portion of the third solar tile structure 36, and the draining channel 43 of the third solar tile structure 36 can be connected to the draining channel 321 of the second solar tile structure 24 for draining the water out of the solar tile structure combination 22 rapidly.

The solar tile structure combination 22 can further include a fourth solar tile structure 44. As shown in FIG. 2, the fourth solar tile structure 44 includes a fourth panel 46 and a fourth supporting plate 48 for supporting the fourth solar panel 46. At least one fourth draining slot 50 is formed on the fourth supporting plate 48 and disposed around the fourth solar panel 46 for draining water surrounding the fourth solar panel 46. The fourth draining slot 50 includes a tenth ditch 501 disposed on a left side of the fourth supporting plate 48, an eleventh ditch 503 disposed on a right side of the fourth supporting plate 48, and a twelfth ditch 505 disposed on an upper side of the fourth supporting plate 48 and connected to the tenth ditch 501 and the eleventh ditch 503. Ends of the tenth ditch 501 and the eleventh ditch 503 far from the twelfth ditch 505 can bend outward the fourth supporting plate 48, so that the water flowing from the twelfth ditch 505 into the tenth ditch 501 and the eleventh ditch 503 can be guided toward two sides of the fourth solar tile structure 44 outwardly, so as to prevent the water from overflowing the fourth draining slot 50 onto the fourth solar panel 46. Besides, a first wedging portion 52 and a second wedging portion 54 can be formed on two lateral sides of the fourth supporting plate 48, and a draining channel 521 is formed on the first wedging portion 52. The fourth solar tile structure 44 can be connected to the adjacent solar tile structures by the first wedging portion 52 and the second wedging portion 54. The draining channel 521 of the fourth solar tile structure 44 can be connected to the draining channel 145 of the first solar tile structure 10 for draining the water leaking from the gap between the corresponding wedging portions of the adjacent solar tile structures.

For assembling the solar tile structure combination 22, the first wedging portion 141 of the first solar tile structure 10 can be wedged with the corresponding second wedging portion of the third solar tile structure 36 tightly, or the second wedging portion 143 of the first solar tile structure 10 can be wedged with the corresponding first wedging portion of the third solar tile structure 36 tightly, so as to combine the first solar tile structure 10 with the third solar tile structure 34 in X direction. In addition, the first wedging portion 52 of the fourth solar tile structure 44 can be wedged with the corresponding second wedging portion 34 of the second solar tile structure 24 tightly, or the first wedging portion 32 of the second solar tile structure 24 can be wedged with the corresponding second wedging portion 54 of the fourth solar tile structure 44 tightly, so as to combine the second solar tile structure 24 with the fourth solar tile structure 44 in X direction. Furthermore, a low side of the first solar tile structure 10 can be engage with the upper side of the fourth solar tile structure 44 in Y direction substantially perpendicular to X direction, and a low side of the third solar tile structure 35 can be engaged with the upper side of the second solar tile structure 24 in Y direction, so as to assemble the solar tile structure combination 22 as the array.

Meanwhile, each draining slot of the solar tile structure combination 22 can drain the water surrounding each solar panel. For preventing the water from overflowing each draining slot onto each solar pane, two ends of each draining slot can bend outward the supporting plate whereon the draining slot is formed for guiding the water out of the solar panels. As shown in FIG. 2, the seventh ditch 421 of the third solar tile structure 35 can be for guiding the water away to the eleventh ditch 503 of the fourth solar tile structure 44, and the second ditch 163 of the first solar tile structure 10 can be for guiding the water away to the fourth ditch 301 of the second solar tile structure 24. For example, part of the water on the first solar tile structure 10 can flow from the third ditch 165 toward the first ditch 161 for draining out of the solar tile structure combination 22, and other part of the water on the first solar tile structure 10 can flow from the third ditch 165 to the second ditch 163 for being guided toward the fourth ditch 301 of the second solar tile structure 24 and for draining out of the solar tile structure combination 22 though the draining channel 521 of the fourth solar tile structure 44. Similarly, part of the water on the third solar tile structure 36 can flow from the ninth ditch 425 to the eighth ditch 423 for draining out of the solar tile structure combination 22, and other part of the water on the third solar tile structure 36 can flow from the ninth ditch 425 to the seventh ditch 421 for being guided toward the eleventh ditch 503 of the fourth solar tile structure 44 and for draining out of the solar tile structure combination 22. It should be mentioned that each draining channel between the adjacent solar tile structures can be connected to the adjacent one in Y direction, as the dotted line shown in FIG. 2, so that the water can flow from the draining channel to the next adjacent draining channel in Y direction for draining out of the solar tile structure combination 22. Structures and functions of the second solar tile structure 24, the third solar tile structure 36, and the fourth solar tile structure 44 are the same as ones of the first solar tile structure 10, and detailed description is omitted herein for simplicity.

Comparing to the prior art, the solar tile structure of the present invention disposes the draining slot around the solar panel, and the draining channel connected to the corresponding draining slot between the adjacent supporting plates, so that the water can be drained out of the solar tile structure rapidly though the draining slot and the draining channel for preventing the solar panel from drenching. The solar tile structure of the present invention not only has simply structure and convenient assembly, but also has a draining system with preferred efficiency for preventing the water from overflowing the draining slot onto the solar panel, effectively.

Those skilled in the art will readily observe that numerous modifications and alterations of the device and method may be made while retaining the teachings of the invention.

What is claimed is:

1. A solar panel tile structure comprising:
a solar panel; and
a supporting plate for supporting the solar panel, at least one draining slot being formed on the supporting plate and disposed around the solar panel for draining water surrounding the solar panel.

2. The solar panel tile structure of claim 1, wherein a first wedging portion and a second wedging portion are formed on two lateral sides of the supporting plate respectively, and the first wedging portion and the second wedging portion are structural portions capable of wedging with each other tightly.

3. The solar panel tile structure of claim 2, wherein a draining channel is formed on the first wedging portion.

4. The solar panel tile structure of claim 1, wherein the draining slot comprises:
a first ditch disposed on a left side of the supporting plate;
a second ditch disposed on a right side of the supporting plate; and
a third ditch disposed on an upper side of the supporting plate and connected to the first ditch and the second ditch.

5. The solar panel tile structure of claim 4, wherein the first ditch is parallel to the second ditch substantially, and the third ditch is perpendicular to the first ditch and the second ditch substantially.

6. The solar panel tile structure of claim 4, wherein ends of the first ditch and the second ditch far from the third ditch bend outward the supporting plate.

7. The solar panel tile structure of claim 1 further comprising:
a junction box disposed on a side of the supporting plate; and
a transmission cable, two ends of the transmission cable being electrically connected to the solar panel and the junction box for transmitting electricity transformed from the solar panel to the junction box.

8. The solar panel tile structure of claim 7 further comprising:
a battery module electrically connected to the junction box for storing the electricity received by the junction box.

9. A solar panel tile structure combination comprising:
a first solar panel tile structure comprising:
a first solar panel; and
a first supporting plate for supporting the first solar panel, at least one first draining slot being formed on the first supporting plate and disposed around the first solar panel for draining water surrounding the first solar panel; and
a second solar panel tile structure connected to the first solar panel tile structure, the second solar panel tile structure comprising:
a second solar panel; and
a second supporting plate for supporting the second solar panel, at least one second draining slot being formed on the second supporting plate and disposed around the second solar panel for draining water surrounding the second solar panel and for draining the water from the first draining slot.

10. The solar panel tile structure combination of claim 9, wherein a first wedging portion and a second wedging portion are formed on two lateral sides of the first supporting plate and the second supporting plate respectively, and the first wedging portion and the second wedging portion are structural portions capable of wedging with each other tightly.

11. The solar panel tile structure combination of claim 10, wherein a draining channel is formed on the first wedging portion.

12. The solar panel tile structure combination of claim 9, wherein the first draining slot comprises:
a first ditch disposed on a left side of the first supporting plate;
a second ditch disposed on a right side of the first supporting plate; and
a third ditch disposed on an upper side of the first supporting plate and connected to the first ditch and the second ditch.

13. The solar panel tile structure combination of claim 12, wherein the first ditch is parallel to the second ditch substantially, and the third ditch is perpendicular to the first ditch and the second ditch substantially.

14. The solar panel tile structure combination of claim 12, wherein ends of the first ditch and the second ditch far from the third ditch bend outward the first supporting plate.

15. The solar panel tile structure combination of claim 12, wherein the second draining slot comprises:
a fourth ditch disposed on a left side of the second supporting plate;
a fifth ditch disposed on a right side of the second supporting plate; and
a sixth ditch disposed on an upper side of the second supporting plate and connected to the fourth ditch and the fifth ditch.

16. The solar panel tile structure combination of claim 15, wherein the fourth ditch is parallel to the fifth ditch substantially, and the sixth ditch is perpendicular to the fourth ditch and the fifth ditch substantially.

17. The solar panel tile structure combination of claim 15, wherein ends of the fourth ditch and the fifth ditch far from the sixth ditch bend outward the second supporting plate.

18. The solar panel tile structure combination of claim 15, wherein the second ditch is for guiding the water toward the fourth ditch.

19. The solar panel tile structure combination of claim 9 further comprising:
a third solar panel tile structure for connecting to the first solar panel tile structure and the second solar panel tile structure, the third solar panel tile structure comprising:
a third solar panel; and
a third supporting plate for supporting the third solar panel, at least one third draining slot being formed on the third supporting plate and disposed around the third solar panel for draining water surrounding the third solar panel; and
a fourth solar panel tile structure for connecting to the first solar panel tile structure and the second solar panel tile structure, the fourth solar panel tile structure comprising:
a fourth solar panel; and
a fourth supporting plate for supporting the fourth solar panel, at least one fourth draining slot being formed on the fourth supporting plate and disposed around the fourth solar panel for draining water surrounding the fourth solar panel and for draining the water from the third draining slot;
wherein the first solar panel tile structure, the second solar panel tile structure, the third solar panel tile structure, and the fourth solar panel tile structure are combined with each other as an array structure.

20. The solar panel tile structure combination of claim 19, wherein a first wedging portion and a second wedging portion are formed on two lateral sides of the third supporting plate respectively, so that the first wedging portion of the first supporting plate is tightly wedged with the second wedging portion of the third supporting plate, or the second wedging portion of the first supporting plate is tightly wedged with the first wedging portion of the third supporting plate.

21. The solar panel tile structure combination of claim 19, wherein the third draining slot comprises:
a seventh ditch disposed on a left side of the third supporting plate;
a eighth ditch disposed on a right side of the third supporting plate; and
a ninth ditch disposed on an upper side of the third supporting plate and connected to the seventh ditch and the eighth ditch; and
the fourth draining slot comprises:
a tenth ditch disposed on a left side of the fourth supporting plate;
an eleventh ditch disposed on a right side of the fourth supporting plate; and
a twelfth ditch disposed on an upper side of the fourth supporting plate and connected to the tenth ditch and the eleventh ditch.

22. The solar panel tile structure combination of claim 21, wherein ends of the seventh ditch and the eighth ditch far from the ninth ditch bend outward the third supporting plate, and ends of the tenth ditch and the eleventh ditch far from the twelfth ditch bend outward the fourth supporting plate.

23. The solar panel tile structure combination of claim 21, wherein the seventh ditch is for guiding the water toward the eleventh ditch.

24. The solar panel tile structure combination of claim 9, wherein the first solar panel tile structure further comprises:
a junction box disposed on a side of the first supporting plate; and
a transmission cable, two ends of the transmission cable being electrically connected to the first solar panel and the junction box for transmitting electricity transformed from the first solar panel to the junction box.

25. The solar panel tile structure combination of claim 24 further comprising:
a battery module electrically connected to the junction box for storing the electricity received by the junction box.
